(19) United States
(12) Patent Application Publication
(10) Pub. No.: US 2011/0304028 A1
(43) Pub. Date: Dec. 15, 2011

(54) SEMICONDUCTOR DEVICE AND METHOD OF MANUFACTURING THE SAME

(75) Inventor: Seung Hwan KIM, Seoul (KR)

(73) Assignee: Hynix Semiconductor Inc., Icheon-si (KR)

(21) Appl. No.: 12/982,745

(22) Filed: Dec. 30, 2010

(30) Foreign Application Priority Data
Jun. 10, 2010 (KR) 10-2010-0054802

(51) Int. Cl. H01L 29/06; H01L 21/768

(52) U.S. Cl. 257/623; 438/643; 257/E29.026; 257/E21.585

(57) ABSTRACT

A semiconductor device which forms a barrier layer formed of a doped polysilicon layer on a buried bit line to prevent the bit line conductive layer from being exposed during the etching process for forming a buried word line, thereby improving characteristics of the device, and a method of manufacturing the same, are provided. The semiconductor device includes a first pillar pattern and a second pillar pattern, including sidewall contacts, and a buried bit line including a bit line conductive layer disposed over a lower part of a trench between the first pillar pattern and the second pillar pattern, and a barrier layer stacked over the bit line conductive layer.

### CROSS-REFERENCES TO RELATED APPLICATION

The present application claims priority to Korean patent application number 10-2010-0054802, filed on 10 Jun. 2010, which is incorporated by reference in its entirety.

### BACKGROUND OF THE INVENTION

The present invention relates to a semiconductor device and a method of manufacturing the same.

As integration of semiconductor devices increases, channel lengths of a transistor becomes shorter. Reduction of the channel length causes short channel effects such as drain induced barrier lowering (DIBL), a hot carrier effect, and punch through. To solve this problem, a method of reducing the depth of a junction region or a method relatively increasing the channel length by forming a recess in a channel region of the transistor has been suggested.

However, as integration of semiconductor memory devices, especially dynamic random access memories (DRAMs), approaches Giga bytes transistors must be fabricated in much smaller sizes. Transistors of Giga byte-graded DRAMs are formed under an 8F2 layout (F: minimum feature size) or a 4F2 layout. Accordingly, although channel length is scaled down, it becomes difficult for a planar transistor structure to meet the new requirements of these layouts. A planar transistor has a stack gate disposed on a semiconductor substrate and junction regions disposed at both sides of the stack gate.

Vertical transistors have been suggested to solve this problem. However, the disadvantage of vertical transistors is the short distance between a buried bit line and a buried word line, such that an upper portion of the buried bit line is exposed during an etching process for forming a buried word line and as a result, the exposed upper portion of the buried bit line is oxidized.

### SUMMARY

According to one aspect of an exemplary embodiment, a semiconductor device is composed of a first pillar pattern and a second pillar pattern, each including a sidewall contact; and a buried bit line including a bit line conductive layer disposed in a lower part between the first pillar pattern and the second pillar pattern and a first barrier layer stacked over the bit line conductive layer.

The sidewall contact is disposed over a sidewall of each of the first pillar pattern and the second pillar pattern.

The bit line conductive layer includes any of tungsten (W), titanium nitride (TiN), and a combination thereof.

The first barrier layer includes a doped polysilicon layer.

The buried bit line is coupled to the sidewall contact.

Further comprising a second barrier metal layer disposed below the bit line conductive layer and over sidewalls of the bit line conductive layer.

The second barrier metal layer includes any of titanium, titanium nitride, and a combination thereof.

Further comprising a third barrier metal layer disposed below the first barrier layer and over sidewalls of the first barrier layer.

The third barrier metal layer includes any of titanium, titanium nitride, and a combination thereof.

A semiconductor device, comprising: a pillar pattern formed over a substrate; a buried bit line pattern formed over a first sidewall of the pillar pattern and coupled to the pillar pattern; a gate pattern formed over a second sidewall of the pillar to be coupled to the buried bit line pattern; and a first barrier pattern formed over the buried bit line pattern to protect the buried bit line from oxidation.

The buried bit line pattern is coupled to the pillar pattern through the first barrier pattern.

The gate pattern is coupled to the buried bit line pattern through a gate insulating layer formed between the pillar pattern and the gate pattern.

Further comprising any of: a second barrier pattern formed at a bottom and a sidewall of the buried bit line pattern; and a third barrier pattern formed at a sidewall of the first barrier pattern, and between the first barrier pattern and the buried bit line pattern.

According to another aspect of an exemplary embodiment, a method of manufacturing a semiconductor device is comprised of forming a first pillar pattern and a second pillar pattern, each including a sidewall contact; and forming a buried bit line including a bit line conductive layer disposed in a lower part between the first pillar pattern and the second pillar pattern and a first barrier layer stacked over the bit line conductive layer.

The forming a buried bit line includes: forming a bit line conductive layer over a semiconductor substrate including the first pillar pattern and the second pillar pattern; etching the bit line conductive layer to be located lower than the sidewall contact; forming the first barrier layer over the first pillar pattern, the second pillar pattern, and the bit line conductive layer; and etching the barrier layer to be located higher than the sidewall contact.

The bit line conductive layer includes any of tungsten, titanium nitride (TiN), and a combination thereof.

The first barrier layer includes a doped polysilicon layer.

The doped polysilicon layer is doped with any of phosphorous (P), arsenic (As), and a combination thereof.

Further comprising: forming a second barrier metal layer over sidewalls and a bottom of the bit line conductive layer.

The second barrier metal layer includes any of titanium, titanium nitride, and a combination thereof.

Further comprising forming a third barrier metal layer over sidewalls and a bottom of the first barrier layer.

The third barrier metal layer includes any of titanium, titanium nitride, and a combination thereof.

Further comprising: forming a capping layer over the buried bit line, the first pillar pattern and the second pillar pattern.

These and other features, aspects, and embodiments are described below in the section entitled “DESCRIPTION OF EXEMPLARY EMBODIMENT”.

### BRIEF DESCRIPTION OF THE DRAWINGS

The summary given above and other aspects, features, and advantages of the present disclosure will be more clearly understood from the following detailed description in conjunction with the s accompanying drawings, in which:

FIG. 1 is a perspective view and a cross-sectional view illustrating a semiconductor device according to an exemplary embodiment of the present invention; and

FIGS. 2A to 2K are perspective views and cross-sectional views illustrating a method of manufacturing a semiconductor device according to an exemplary embodiment of the present invention.

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations that result from, for example, manufacturing techniques and/or tolerances, are to be expected. Thus, exemplary embodiments should not be construed as limited to the particular shapes of regions illustrated herein but may also include deviations in shapes that may result from, for example, manufacturing. In the drawings, the lengths and sizes of layers and regions may be exaggerated for clarity. Like reference numerals in the drawings denote like elements. It is also understood that when a layer is referred to as being “on” another layer or substrate, it may mean that the layer is directly over the other layer or substrate, or that intervening layers may also be present.

Hereinafter, a semiconductor device and a method of manufacturing the same according to an exemplary embodiment of the present invention will be described in more detail with reference to accompanying drawings.

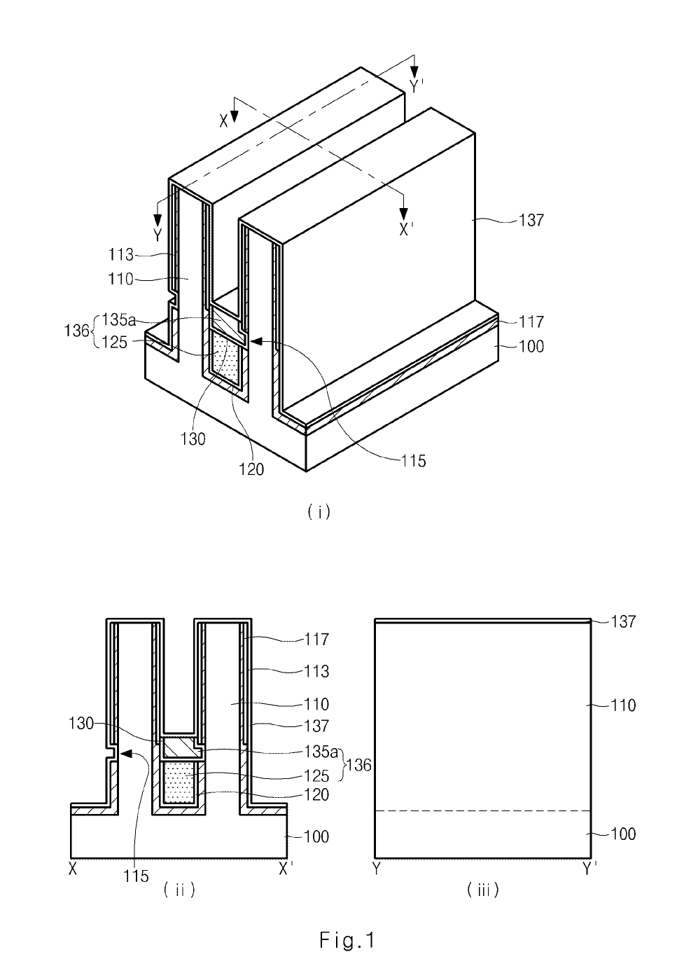

FIG. 1 illustrates a semiconductor device according to an exemplary embodiment of the present invention. Specifically, FIG. 1 illustrates a semiconductor device in which a buried word line and a buried bit line are formed. In FIG. 1, (i) is a perspective view, (ii) is a cross-sectional view taken along the line X-X′ of (i), and (iii) is a cross-sectional view taken along the line Y-Y′ of (i).

Referring to FIG. 1, a plurality of pillar patterns 110, each of which includes a sidewall contact 115, are included on a semiconductor substrate 100. The pillar patterns 110 are line patterns extending along the Y-Y′ direction. The sidewall contact 115 is formed to expose a portion of one sidewall of pillar pattern 110 under a liner oxide layer 113 and a liner nitride layer 117. A buried bit line 136 is disposed over the semiconductor substrate 100 between a pillar pattern 110 and an adjacent pillar pattern 110. The buried bit line 136 may include a stack structure composed of a bit line conductive layer 125 and a barrier layer 135a. The bit line conductive layer 125 may include tungsten and the top of the bit line conductive layer 125 is preferably the same height as the bottom of the sidewall contact 115. In addition, the barrier layer 135a may include a doped polysilicon layer and may extend to a level higher than the top of the sidewall contact 115. Here, the barrier layer 135a may be disposed over the bit line conductive layer 125 to prevent the bit line conductive layer 125 from being exposed, thereby preventing the bit line conductive layer 125 from being oxidized. A first barrier metal layer 120 is disposed below the buried bit line 136 in such a manner that it surrounds the buried bit line 136. The second barrier metal layer 130 is disposed between the bit line conductive layer 125 and a barrier layer 135a.

As described above, buried bit line 136 of an embodiment of the semiconductor is structured such that the bit line conductive layer 125 and the barrier layer 135a are oriented to prevent the bit line conductive layer 125 from being exposed.

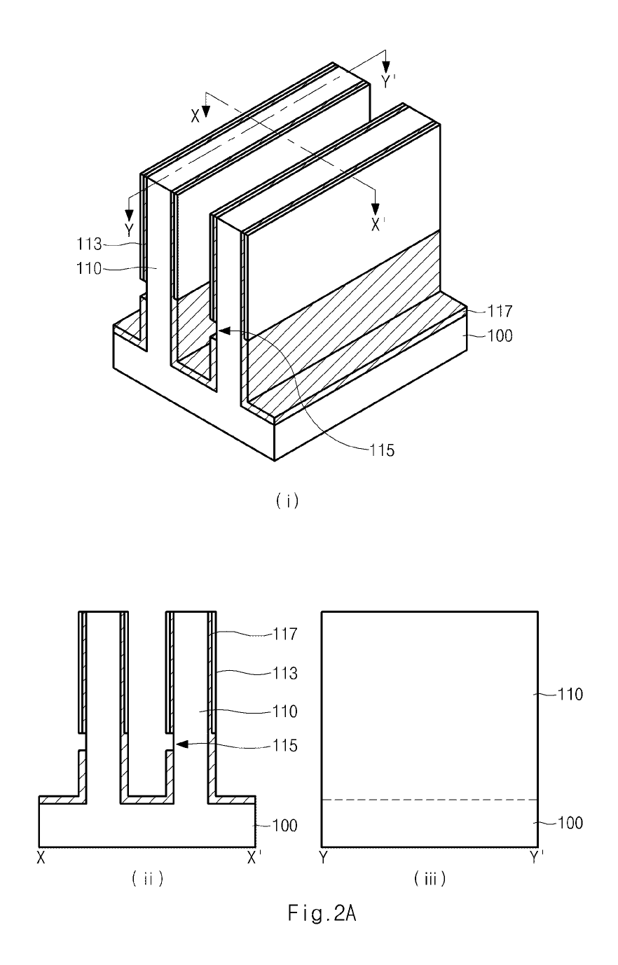

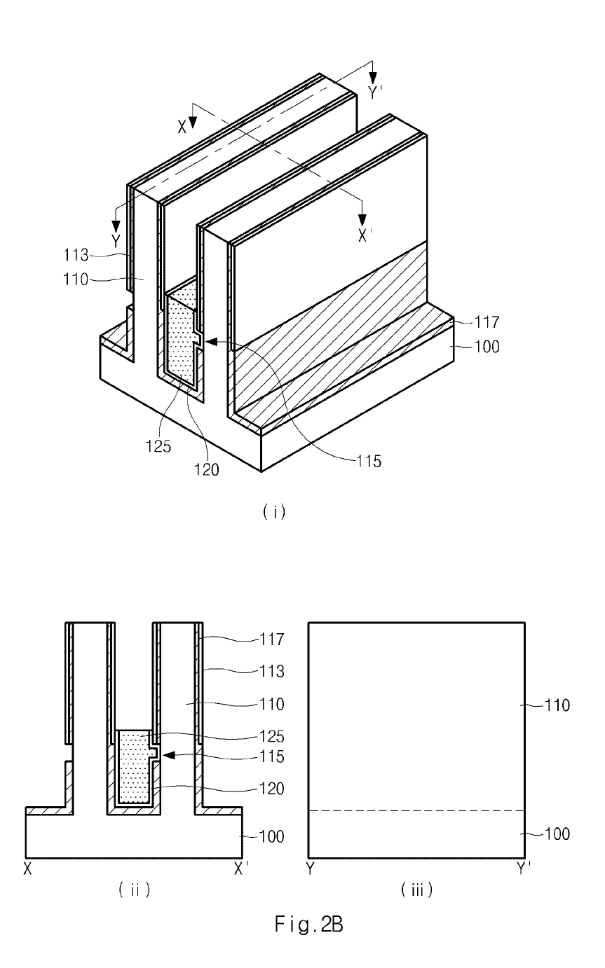

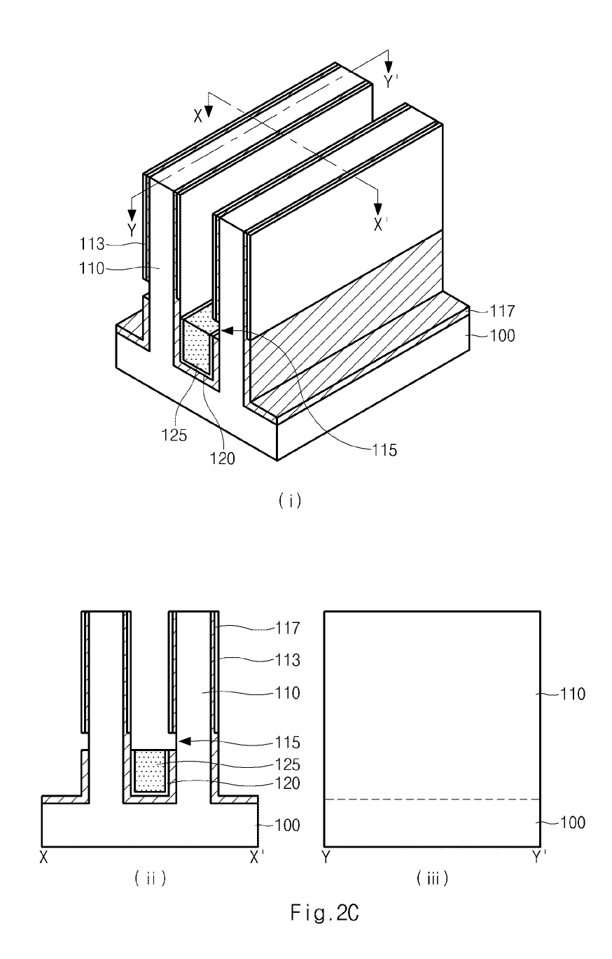

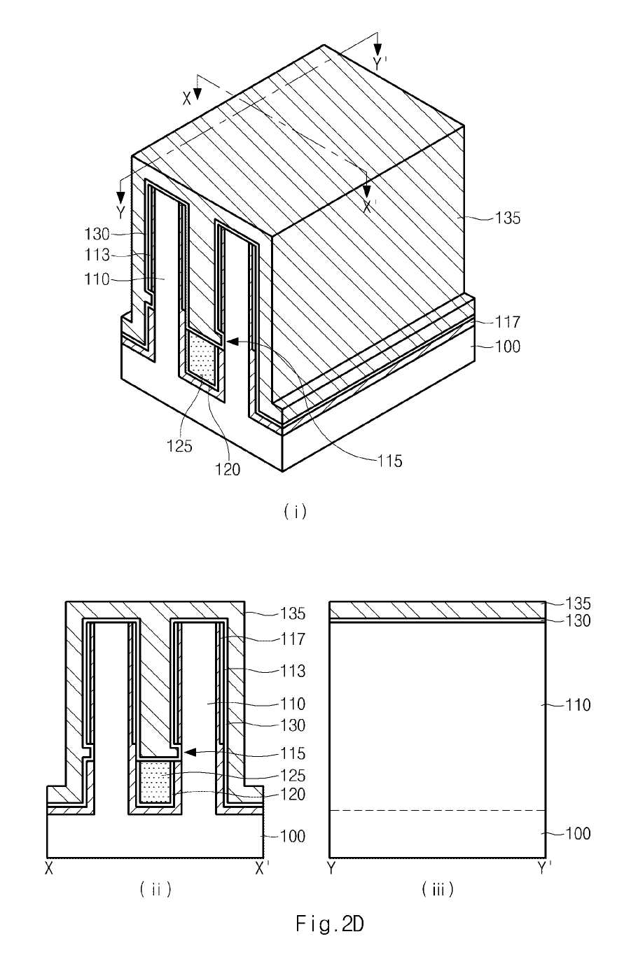

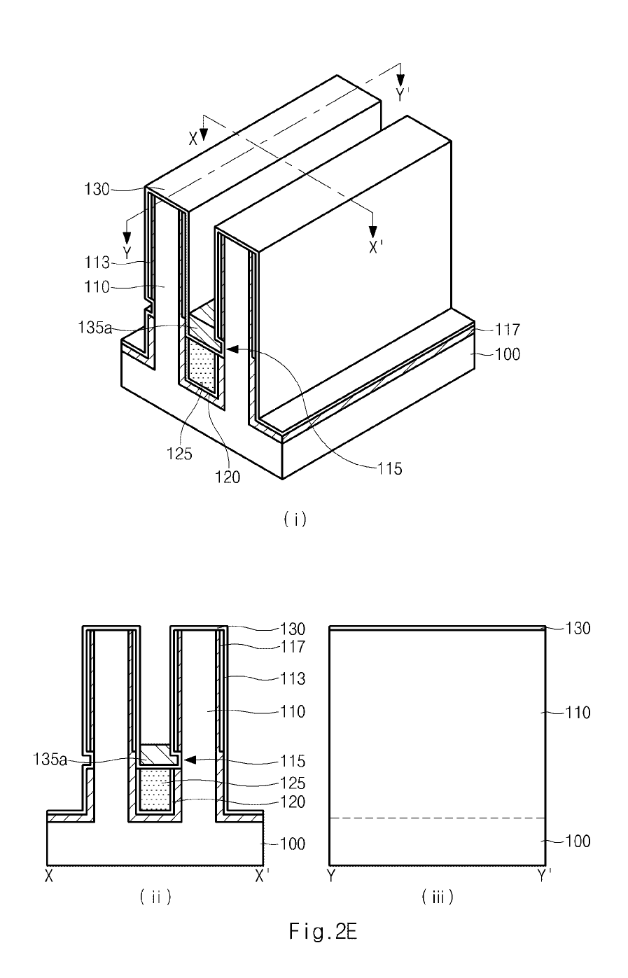

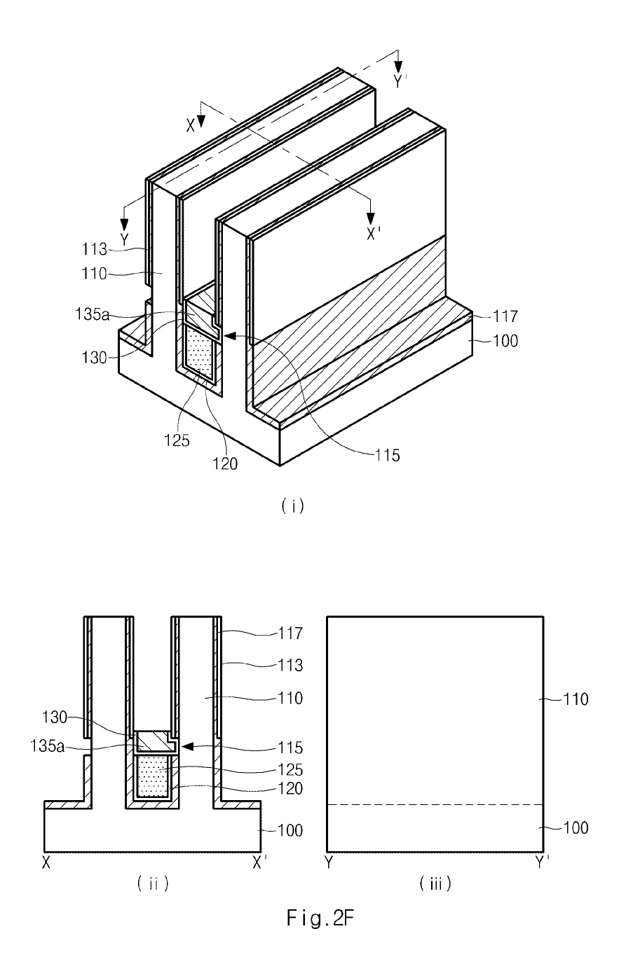

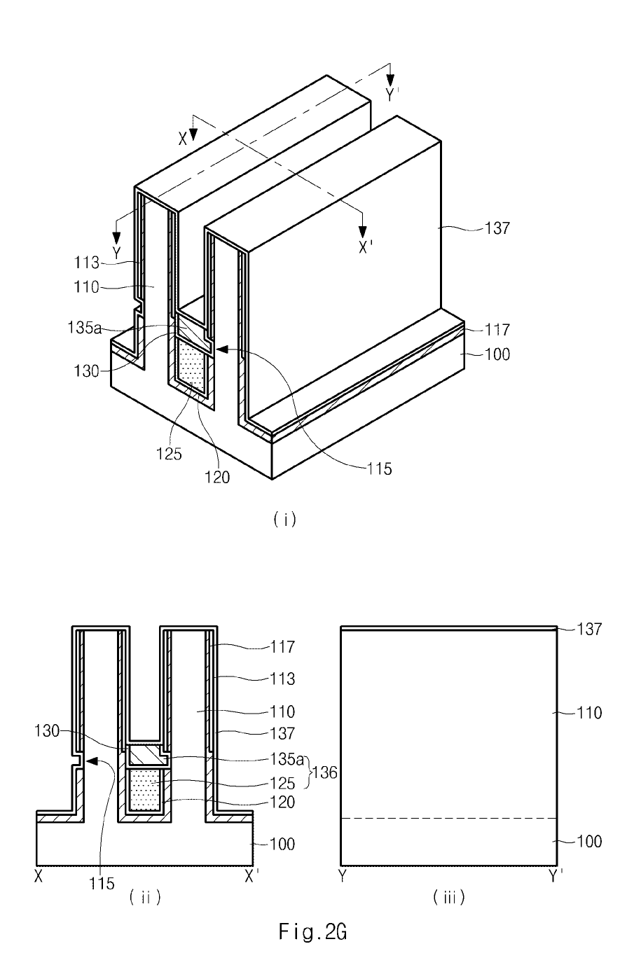

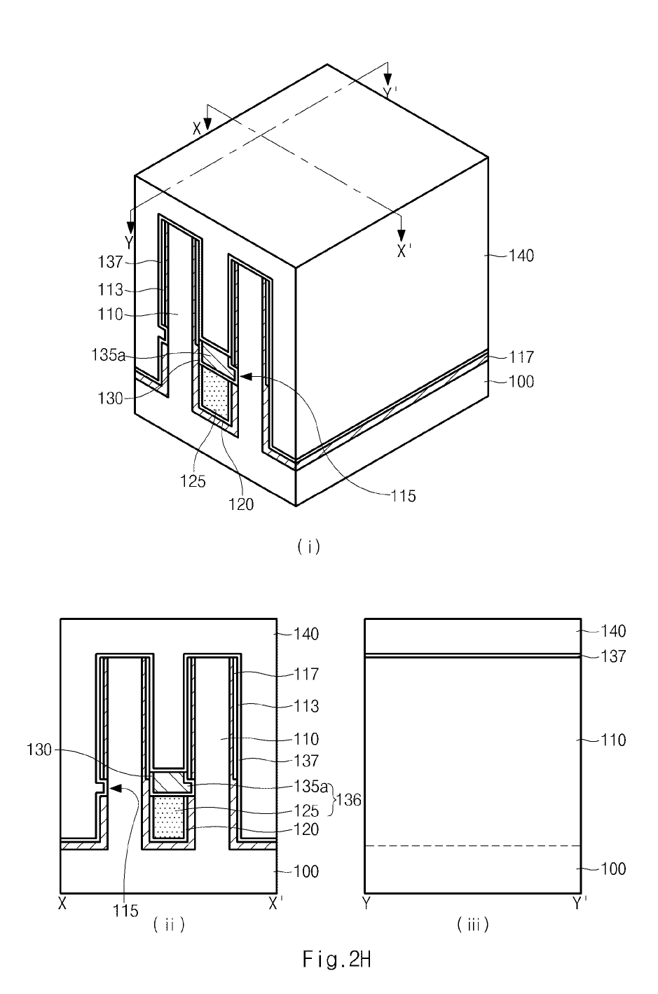

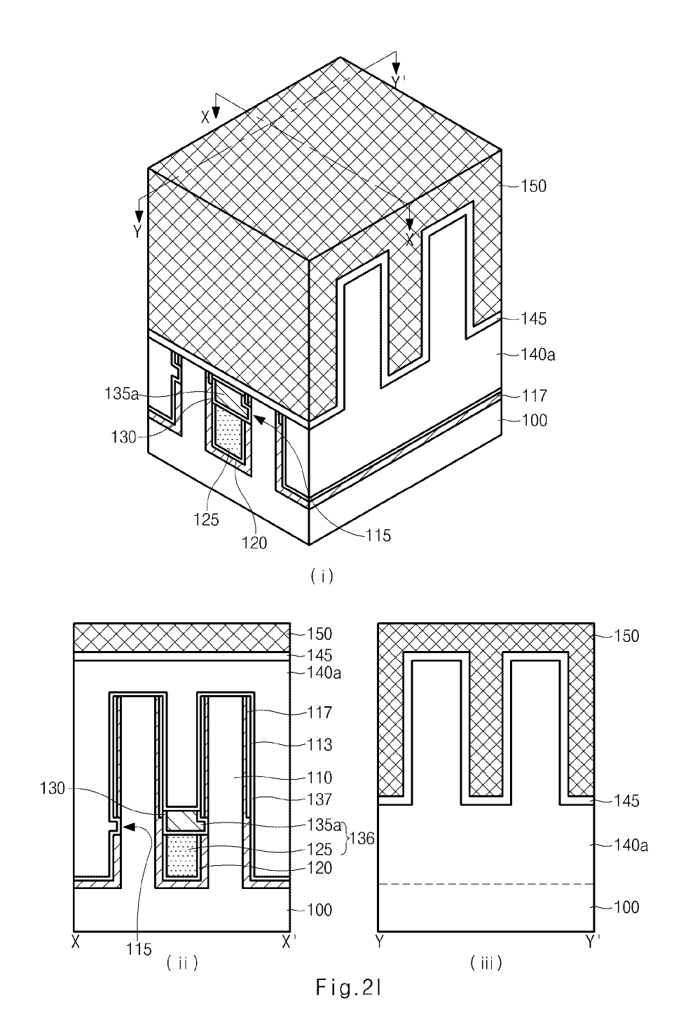

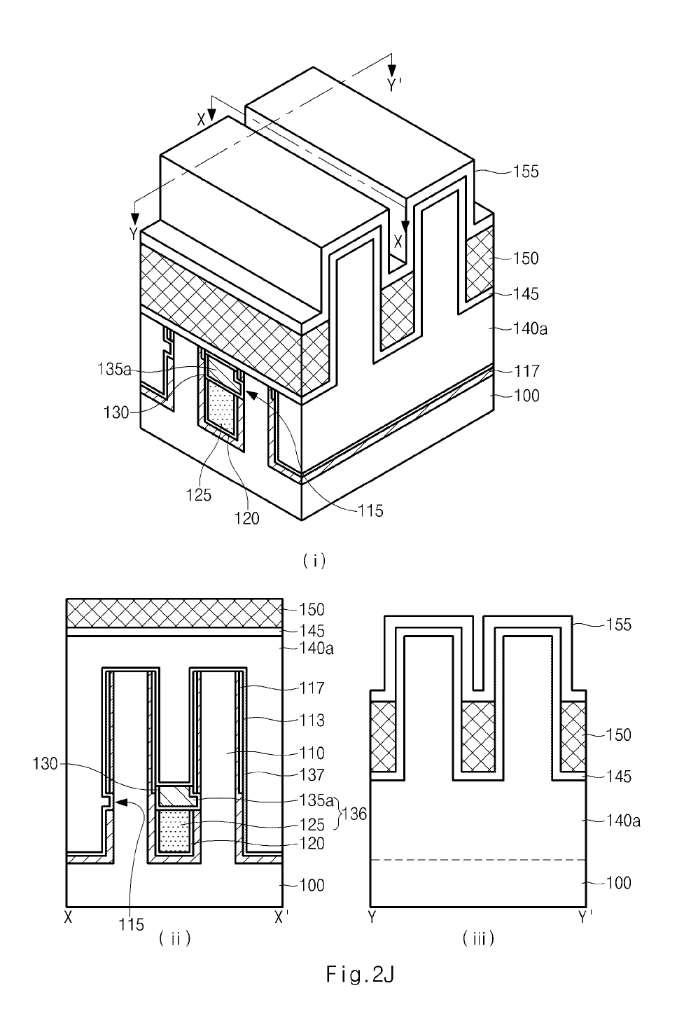

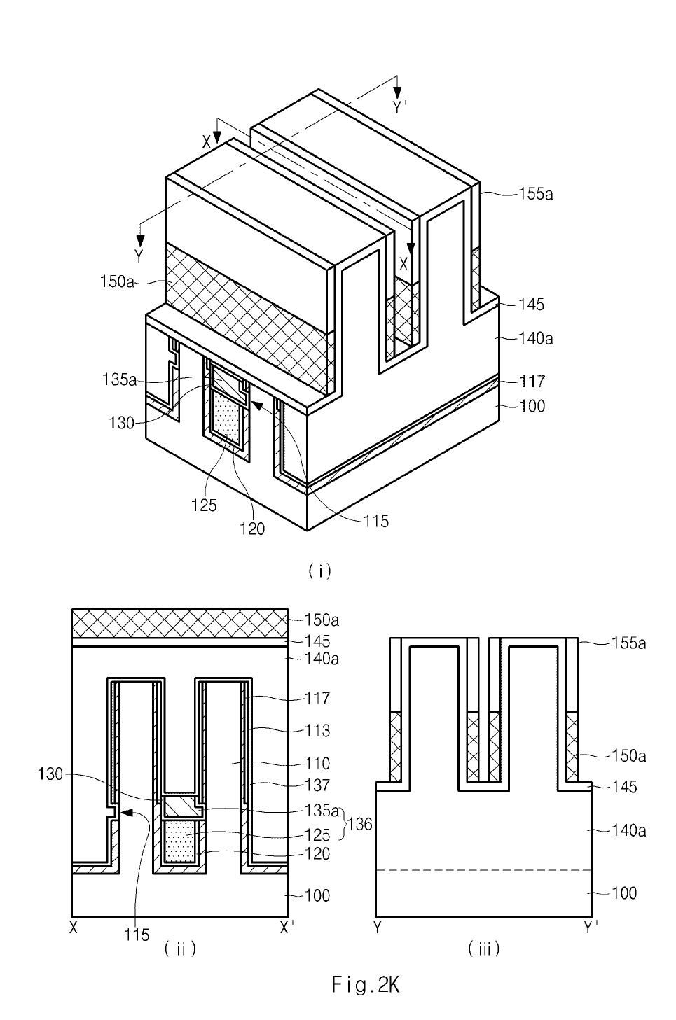

FIGS. 2A to 2K illustrate a method of manufacturing a semiconductor device according to an exemplary embodiment of the present invention. In FIGS. 2A to 2K, (i) is a perspective view, (ii) is a cross-sectional view taken along the line X-X′ of (i), and (iii) is a cross-sectional view taken along the line Y-Y′ of (i). Referring to FIG. 2A, a mask pattern (not shown) defining a buried bit line region is formed on a semiconductor substrate 100. At this time, the mask pattern may be formed in a line pattern.

The semiconductor substrate 100 is etched using the mask pattern as an etching mask to form a plurality of pillar patterns 110. A pillar pattern 110 is formed, extending in the Y-Y′ direction, by etching a portion of the semiconductor substrate 100. Next, a liner oxide layer 113 and a liner nitride layer 117 are formed defining sidewall contacts on surfaces of the pillar patterns 110. At this time, the liner oxide layer 113 and the liner nitride layer 117 are formed on only a portion of one side of each pillar pattern 110. Herein, the pillar pattern 110 exposed by patterning the liner oxide layer 113 and the liner nitride layer 117 becomes the sidewall contact 115. The sidewall contact 115 has a one side contact (OSC) structure which is formed only over one sidewall thereof.

Referring to FIG. 2B, a first barrier metal layer 120 is deposited over the semiconductor substrate 100, including the pillar pattern 110 on which the sidewall contact 115 is formed. The first barrier metal layer 120 may include any one of titanium, titanium nitride, and a combination thereof.

Next, a bit line conductive layer 125 is formed over the semiconductor substrate 100 on which the first barrier metal layer 120 is formed. The bit line conductive layer 125 may include a material containing tungsten and may be formed at a thickness of 2000 to 2500 Å. The bit line conductive layer 125 is etched back to a predetermined depth. The bit line conductive layer 125 may be etched back from the upper side of the sidewall contact 115 to be 80 to 120 Å. While the bit line conductive layer 125 is etched, the first barrier metal layer 120 is also etched to be at the same level as the bit line contact layer 125.

Referring to FIG. 2C, an upper portion of the etched bit line conductive layer 125 is further etched. The etching process is performed by a wet cleaning process. The wet cleaning process uses the lower side of the sidewall contact 115 as an etching target. The wet cleaning process may be performed until the sidewall contact 115 is completely exposed. While the upper portion of the bit line conductive layer 125 is etched, the first barrier metal layer 120 is also etched to be at the same level as the bit line conductive layer 125.

Referring to FIG. 2D, a second barrier metal layer 130 is deposited on the surface of the semiconductor substrate 100 including the bit line conductive layer 125 and the pillar pattern 110. Next, a polysilicon layer 135 is formed over the semiconductor substrate 100 including the pillar pattern 110 on which the second barrier metal layer 130 is formed. The polysilicon layer 135 may include a doped polysilicon layer where one or more dopants, such as phosphorous (P) and arsenic

(As), are doped. The second barrier metal layer 130 is formed over the bit line conductive layer 125, and the polysilicon layer 135 is formed over the second barrier metal layer 130. At this time, if the thickness of the second barrier metal layer 130 is too thin, a reaction between the tungsten of the bit line conductive layer 125 and the polysilicon layer 135 will occur, but if the thickness of the second barrier metal layer 130 is too thick, doping will be suppressed by the second barrier metal layer 130. Accordingly, the second barrier metal layer 130 needs to be formed with a narrow tolerance thickness, preferably, 50 to 70 Å.

Referring to FIG. 2E, the polysilicon layer 135 is etched by an etch back process to form a barrier layer 135a. At this time, an etching target may be preferably set as the same height as the sidewall contact 115 or higher. In the embodiment illustrated in FIG. 2E, the polysilicon layer is formed at a lower level than the top of the sidewall contact 115. Referring to FIG. 2F, the second barrier metal layer 130 exposed by the barrier layer 135a is removed to form a buried bit line. That is, the buried bit line is formed of a stacking structure of the bit line conductive layer 125 and the barrier layer 135a. The barrier layer 135a is formed to prevent the bit line conductive layer 125 from being exposed during the following etching process for a buried word line.

FIG. 2G, a capping layer is deposited over the semiconductor substrate 100 including the barrier layer 135a and the pillar pattern 110. The capping layer 137 may include a material containing a nitride layer. Like the barrier layer 135a, the capping layer 137 is formed to prevent the bit line conductive layer 125 from being oxidized. Accordingly, the capping layer 137 serves as a primary barrier to prevent oxidation, and if the capping layer 137 is damaged, the barrier layer 135a serves as a secondary barrier to prevent oxidation.

Referring to FIG. 2H, an oxide layer 140 is formed over the semiconductor substrate 100 including the pillar pattern 110 on which the capping layer 137 is formed. The oxide layer 140 may include one or more layers of a spin on dielectric (SOD) oxide layer and a high density plasma (HDP) oxide layer. Preferably, the SOD oxide layer and the HDP oxide layer may be sequentially stacked to form the oxide layer 140.

Referring to FIG. 21, a mask pattern (not shown) defining a buried word line region is formed over the oxide layer 140. The mask pattern is formed in a line pattern and may be extended in the X-X′ direction, perpendicular to the buried bit line 136. Next, the oxide layer is etched using the mask pattern as an etching mask to form an oxide layer pattern 140a and expose the buried word line region. In the buried word line region, a buried word line is to be formed in the process that follows. The process for forming the oxide layer pattern 140a is performed until the capping layer 137 over the buried bit line is exposed. Although the capping layer 137 is over-etched to be damaged in the etching process, the barrier layer 135a is formed over the bit line conductive layer 125 to prevent the bit line conductive layer 125 from being exposed and oxidized. Next, a gate insulation film 145 is formed over the semiconductor substrate 100 including the oxide layer pattern 140a. And a word line conductive layer 150 is formed over the substrate 100 including the gate insulation film 145.

Referring to FIG. 2J, the word line conductive layer 150 remains only on a lower part between the oxide patterns 140a by performing an etch back process. Next, a spacer material 155 is deposited over the semiconductor substrate 100 including the oxide pattern 140a and the word line conductive layer 150. The spacer material 155 may include any of an oxide layer, a nitride layer, and a combination thereof. Preferably, the spacer material 155 may be formed sequentially of a stack of a nitride layer and an oxide layer. The spacer material 155 may be formed at a thickness of 350 to 450 angstroms.

Referring to FIG. 2K, spacers 155a are formed over sidewalls of the oxide pattern 140a by performing an etch back process. Next, the word line conductive layer 150 is etched using the spacers 155 as a mask to form the buried word line 150a on the sidewalls of the oxide layer pattern 140a.

As described above, the barrier layer 130 formed of a doped polysilicon layer is formed over the buried bit line 136. Therefore, in the etching process for forming the buried word line 150a, it prevents the bit line conductive layer 125 from being exposed and oxidized, thereby improving characteristics of the device.

The above embodiment of the present invention is illustrative and not limitative. Various alternatives and equivalents are possible. The invention is not limited by the embodiment described herein, nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a first pillar pattern and a second pillar pattern, each including a sidewall contact; and
a buried bit line including a bit line conductive layer disposed in a lower part between the first pillar pattern and the second pillar pattern and a first barrier layer stacked over the bit line conductive layer.

2. The semiconductor device of claim 1, wherein the sidewall contact is disposed over a sidewall of each of the first pillar pattern and the second pillar pattern.

3. The semiconductor device of claim 1, wherein the bit line conductive layer includes any of tungsten (W), titanium nitride (TiN), and a combination thereof.

4. The semiconductor device of claim 1, wherein the first barrier layer includes a doped polysilicon layer.

5. The semiconductor device of claim 1, wherein the buried bit line is coupled to the sidewall contact.

6. The semiconductor device of claim 1, further comprising a second barrier metal layer disposed below the bit line conductive layer and over sidewalls of the bit line conductive layer.

7. The semiconductor device of claim 6, wherein the second barrier metal layer includes any of titanium, titanium nitride, and a combination thereof.

8. The semiconductor device of claim 1, further comprising a third barrier metal layer disposed below the first barrier layer and over sidewalls of the first barrier layer.

9. The semiconductor device of claim 8, wherein the third barrier metal layer includes any of titanium, titanium nitride, and a combination thereof.

10. A method of manufacturing a semiconductor device, comprising:
forming a first pillar pattern and a second pillar pattern, each including a sidewall contact; and
forming a buried bit line including a bit line conductive layer disposed in a lower part between the first pillar pattern and the second pillar pattern and a first barrier layer stacked over the bit line conductive layer.

11. The method of claim 10, wherein the forming a buried bit line includes:
forming a bit line conductive layer over a semiconductor substrate including the first pillar pattern and the second pillar pattern;
etching the bit line conductive layer to be located lower than the sidewall contact;
forming the first barrier layer over the first pillar pattern, the second pillar pattern, and the bit line conductive layer; and
etching the barrier layer to be located higher than the sidewall contact.

12. The method of claim 10, wherein the bit line conductive layer includes any of tungsten, titanium nitride (TiN), and a combination thereof.

13. The method of claim 10, wherein the first barrier layer includes a doped polysilicon layer.

14. The method of claim 13, wherein the doped polysilicon layer is doped with any of phosphorous (P), arsenic (As), and a combination thereof.

15. The method of claim 10, further comprising:
forming a second barrier metal layer over sidewalls and a bottom of the bit line conductive layer.

16. The method of claim 15, wherein the second barrier metal layer includes any of titanium, titanium nitride, and a combination thereof.

17. The method of claim 10, further comprising forming a third barrier metal layer over sidewalls and a bottom of the first barrier layer.

18. The method of claim 17, wherein the third barrier metal layer includes any of titanium, titanium nitride, and a combination thereof.

19. The method of claim 10, further comprising:
forming a capping layer over the buried bit line, the first pillar pattern and the second pillar pattern.

20. A semiconductor device, comprising:
a pillar pattern formed over a substrate;
a buried bit line pattern formed over a first sidewall of the pillar pattern and coupled to the pillar pattern;
a gate pattern formed over a second sidewall of the pillar to be coupled to the buried bit line pattern; and
a first barrier pattern formed over the buried bit line pattern to protect the buried bit line from oxidation.
